(19) United States
(12) Patent Application Publication
(10) Pub. No.: US 2006/0054963 A1
(43) Pub. Date: Mar. 16, 2006

(54) Non-volatile and non-uniform trapped-charge memory cell structure and method of fabrication

(76) Inventors: Rong A. Qian, Hsinchu (TW); Yen-Hui Ku, Hsinchu (TW)

Correspondence Address: Kenton R. Mullins;Stout, Uxa, Buyan & Mullins, LLP, Suite 300, 4 Venture, Irvine, CA, 92618, US

(21) Appl. No.: 10/938,325

(22) Filed: Sep. 10, 2004

(51) Int. Cl. H01L 29/76

(52) U.S. Cl. 257/314

(57) ABSTRACT

A memory cell having a charge-trapping structure in the form of a layer of conductive clusters disposed between upper and lower insulator layers is disclosed. The memory cell can otherwise be constructed and operated similarly to a nitride read-only memory cell.

### BACKGROUND OF THE INVENTION

1. Field of the Invention

The present invention relates generally to non-volatile memory devices and, more particularly, to apparatus non-uniform, trapped-charge memory cell structures capable of storing two bits per cell.

2. Description of Related Art

A non-volatile semiconductor memory device is designed to retain programmed information in the presence or absence of electrical power. Read-only memory (ROM) is a non-volatile memory device commonly used in electronic equipment such as microprocessor-based digital equipment and portable devices.

Typical ROM devices include multiple-memory cell arrays. Each memory-cell array may be visualized as including intersecting word lines and bit lines. Each word-line and bit-line intersection can correspond to one bit of memory. In mask metal-oxide semiconductor (MOS) ROM (aka MROM) devices, the presence or absence of a MOS transistor at word and bit line intersections distinguishes between a stored logic ‘0’ and logic ‘1’.

A programmable read-only memory (PROM) is similar to the MROM except that a user may store data values (i.e., program the PROM) using a PROM programmer. A PROM device is typically manufactured with fusible or anti-fusible links at all word and bit line intersections. This corresponds to having all bits at a particular logic value, typically logic ‘1’. The PROM programmer is used to set desired bits to the opposite logic value, typically by applying a high voltage that fuses or anti-fuses the links corresponding to the desired bits. A typical PROM device can only be programmed once.

An erasable programmable read-only memory (EPROM) is programmable in a manner similar to the PROM, but can also be erased (e.g., to an all logic ‘1’s state) by exposing it to ultraviolet light. A typical EPROM device has a floating gate MOS transistor at all word and bit line intersections (i.e., at every bit location). Each MOS transistor has two gates: a floating gate and a non-floating gate. The floating gate is not electrically connected to any conductor, and is surrounded by a high impedance insulating material. To program the EPROM device, a high voltage is applied to the non-floating gate at each bit location where a logic value (e.g., a logic ‘0’) is to be stored. This causes the insulating material to break down and permits negative charges to accumulate on the floating gate. When the high voltage is removed, the negative charges remain on the floating gate. During subsequent read operations, the negative charges prevent the MOS transistor from forming a low-resistance channel between a drain terminal and a source terminal (i.e., from switching on) when the transistor is selected.

An EPROM integrated circuit is normally housed in a package having a quartz lid; the EPROM is erased by exposing the EPROM integrated circuit to ultraviolet light passed through the quartz lid. The insulating material surrounding the floating gates becomes slightly conductive when exposed to the ultraviolet light, allowing the accumulated negative charges on the floating gates to dissipate.

A typical electrically erasable programmable read-only memory (EEPROM) device is similar to an EPROM device except that individual stored bits may be erased electrically. The floating gates in the EEPROM device are surrounded by a considerably thinner insulating layer, and accumulated negative charge on the floating gates can be dissipated by applying a voltage having a polarity opposite that of the programming voltage to the non-floating gates.

Flash memory devices are sometimes referred to as flash EEPROM devices, and differ from EEPROM devices in that electrical erasure involves large sections of, or the entire contents of, a flash memory device. A relatively recent development in non-volatile memory is localized trapped-charge devices. While certain ones of these devices are commonly referred to as nitride read-only memory (NROM) devices, the acronym “NROM” is a part of a combination trademark of Saifun Semiconductors Ltd. (Netanya, Israel). Certain nitride read-only memory devices permit the storage of two physical bits of information per memory cell. Multiple-Level Cell (MLC) technology permits the storage of plural bits of information per memory cell if precise levels of trapped-charge can be localized on a floating gate.

A common problem in the related art is that a broad distribution of charge-trapped in an nitride read-only memory device causes the two adjacent bits stored in each memory cell to interfere with each other for device geometries smaller than, for example, about 0.25 μm. For such relatively small-device geometries, this can reduce scalability and data-retention performance through immigration of charges that are not well localized.

Another common problem in the related art is that typical methods of fabricating floating-gate MLC devices require a larger number of mask levels than typical methods of fabricating nitride read-only memory devices. This results in higher-complexity processes at increased cost.

Thus, needs exist in the related art for non-volatile and localized trapped-charge memory cell structures capable of storing two bits per cell at geometries smaller than about 0.25 μm with sufficient scalability and data-retention performance.

### SUMMARY OF THE INVENTION

The present invention addresses these needs by providing a non-volatile, non-uniform trapped-charge memory cell capable of storing two bits per cell and a simple method of fabricating the non-uniform trapped-charge memory cell with sufficient scalability and data retention performance.

The non-uniform trapped-charge memory cell comprises a transistor formed on a substrate with a source, a drain, a channel under a non-uniform charge-trapping structure (between the source and the drain), a gate overlying the charge-trapping structure, the charge-trapping structure comprising a conductive non-uniform thin-film grown at an interface between materials with heterogeneous lattices, referred to below as a heterogeneous material interface.

The method of fabricating a non-uniform trapped-charge memory cell comprises forming a transistor by providing a substrate, depositing a tunneling oxide layer on the substrate, forming a charge-trapping layer by growing a plurality of heterogeneous conductive clusters, performing in-situ doping on the heterogeneous conductive clusters; oxidizing the surface of the charge-trapping layer to seal the surfaces and boundaries of the heterogeneous conductive clusters, forming a conductive polysilicon layer on the oxidized surface of the charge-trapping layer to form a gate, etching the resulting structure, and implanting source and drain regions.

When the non-uniform trapped-charge memory cell is operating, localized charges will remain trapped in the heterogeneous conductive clusters disposed near the corners of the source and drain around the interfaces with tunneling oxide surroundings. This tight localization of trapped-charge enables aggressive scaling of the charge-trapping layer as well as the transistor.

While the apparatus and method has or will be described for the sake of grammatical fluidity with functional explanations, it is to be expressly understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112 are to be accorded full statutory equivalents under 35 USC 112.

Any feature or combination of features described herein are included within the scope of the present invention provided that the features included in any such combination are not mutually inconsistent as will be apparent from the context, this specification, and the knowledge of one skilled in the art. For purposes of summarizing the present invention, certain aspects, advantages and novel features of the present invention are described herein. Of course, it is to be understood that not necessarily all such aspects, advantages or features will be embodied in any particular embodiment of the present invention. Additional advantages and aspects of the present invention are apparent in the following detailed description and claims that follow.

### BRIEF DESCRIPTION OF THE DRAWINGS

FIG. 1 is a memory cell structure with a non-uniform charge-trapping structure;

FIG. 2a is a uniform mode of thin-film growth at a heterogeneous material interface;

FIG. 2b is a non-uniform mode of thin-film growth at a heterogeneous material interface;

FIGS. 3-4b depict steps implemented in the fabrication of a non-uniform charge-trapping structure of a memory cell;

FIG. 5 is a memory cell with a plurality of layers of heterogeneous conductive clusters that form a plurality of non-uniform charge-trapping structures with increased capacity;

FIG. 6a shows an ideal distribution of trapped charges within a non-uniform charge-trapping memory cell in accordance with the present invention;

FIG. 6b shows a distribution of trapped charge within a conventional trapped-charge memory cell; and

FIGS. 7-10 illustrate the storage of charges in a non-uniform charge-trapping memory cell in accordance with the programming states (11), (01), (10) and (00).

### DETAILED DESCRIPTION OF THE PRESENTLY PREFERRED EMBODIMENTS

Reference will now be made in detail to the presently preferred embodiments of the invention, examples of which are illustrated in the accompanying drawings. Wherever possible, the same or similar reference numbers are used in the drawings and the description to refer to the same or like parts. It should be noted that the drawings are in simplified form and are not to precise scale. In reference to the disclosure herein, for purposes of convenience and clarity only, directional terms, such as, top, bottom, left, right, up, down, over, above, below, beneath, rear, and front, are used with respect to the accompanying drawings. Such directional terms should not be construed to limit the scope of the invention in any manner.

Although the disclosure herein refers to certain illustrated embodiments, it is to be understood that these embodiments are presented by way of example and not by way of limitation. The intent of the following detailed description, although discussing exemplary embodiments, is to be construed to cover all modifications, alternatives, and equivalents of the embodiments as may fall within the spirit and scope of the invention as defined by the appended claims. It is to be understood and appreciated that the process steps and structures described herein do not cover a complete process flow for the manufacture of non-volatile memory cells. The present invention may be practiced in conjunction with various integrated-circuit fabrication techniques that are conventionally used in the art, and only so much of the commonly practiced process steps are included herein as are necessary to provide an understanding of the present invention. The present invention has applicability in the field of semiconductor devices and processes in general. For illustrative purposes, however, the following description pertains to a method of fabricating a non-uniform charge-trapping memory cell.

In accordance with one aspect of the present invention, a non-volatile memory cell comprises a non-uniform trapped-charge memory cell capable of storing charges in discrete clusters and providing multiple bits per cell. One embodiment of the non-volatile memory cell can comprise an electrically erasable programmable read-only memory (EEPROM) cell, which can be erased using, for example, positive or negative Fowler-Nordheim tunneling and which has both an up bit (e.g., source bit) and a down bit (e.g., drain bit), each of which may be separately programmed (e.g. set to a non-erased state).

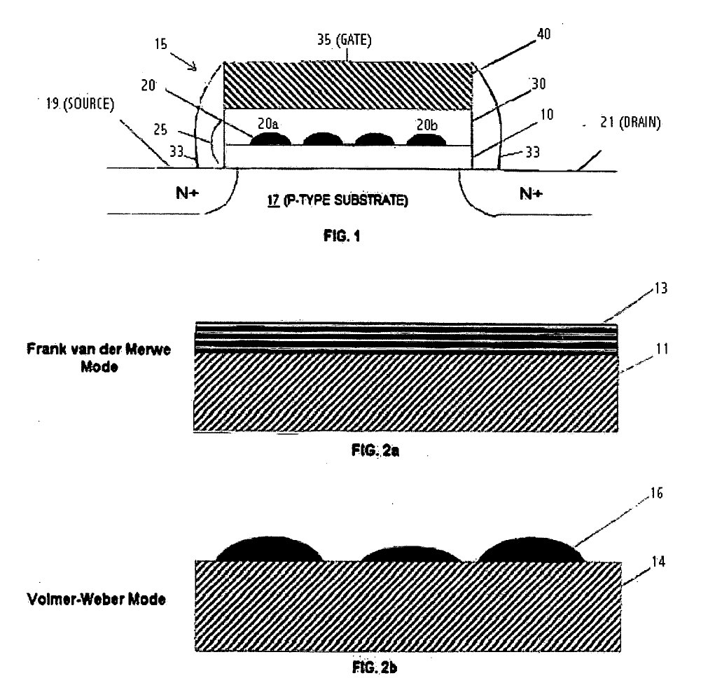

Referring more particularly to the drawings, FIG. 1 is a cross-sectional diagram of an exemplary embodiment of a non-uniform trapped-charge memory cell 15 fabricated in accordance with the present invention. As presently embodied, the non-uniform trapped-charge memory cell 15 comprises a transistor formed on a substrate 17. The substrate 17 may comprise, for example, silicon, and further may be doped with holes to form a p-type substrate. The transistor comprises a source region 19 and a drain region 21. The source 19 and the drain 21 may be heavily doped with n-type impurities. Accordingly, these regions are designated as N+ type regions. The region of the substrate 17 between the source 19 and the drain 21 is referred to as the channel of the transistor.

A non-uniform charge-trapping structure 25 overlies the channel. In accordance with the illustrated embodiment, the non-uniform charge-trapping structure 25 comprises a three-layer structure including a layer of heterogeneous conductive clusters 20 disposed between two insulator layers. As presently embodied, these two insulator layers comprise a bottom or tunneling silicon dioxide (oxide) layer 10 which serves as a tunneling oxide layer and a top oxide layer 30. As will be discussed in greater detail below, heterogeneous clusters can be grown and in-situ doped above the bottom oxide layer 10, to thereby form heterogeneous conductive clusters 20, prior to the resulting structure being capped with the top oxide layer 30. A conducting layer, referred to as a gate 40, overlies the non-uniform charge-trapping structure 25.

While not wishing to be limited, an exemplary approach for generating oxide-encased heterogeneous conductive clusters 20 (FIG. 1) is now described with reference to FIGS. 2a and 2b. These two figures elucidate comparative processes which may be relevant in describing and generating modes of thin-film growth at heterogeneous material interfaces.

FIG. 2a exemplifies a Frank van der Merwe mode of growing at least one uniform, thin-film 13 over a substrate layer 11. In the illustrated embodiment, the thin-film 13 can comprise epitaxially grown gallium-arsenate, and the substrate layer 11 can comprise germanium, wherein a heterogeneous material interface is formed between the thin film 13 and the substrate layer 11. The Frank Van der Merwe mode growth occurs layer-by-layer and comprises deposition of one two-dimensional layer at a time, resulting in a smooth epitaxial film. Frank Van der Merwe mode growth occurs when an energy density of the interface strain (σᵢ) and energy density of the native film (σ_{f}) are, additively, less than the energy density of the substrate (σₛ). However, to the extent that more than one conductive thin film 13 is added, a cohesion between the film and substrate decreases incrementally as each new film layer is added.

Another mode of growing a type of conductive thin film is shown in FIG. 2b, wherein a Volmer-Weber mode is used to grow a non-uniform thin film 16 over a substrate layer 14. The non-uniform thin film 16 can correspond to, or be subsequently processed to correspond to, the heterogeneous conductive clusters 20 (FIG. 1), and the substrate layer 14 can correspond to the bottom oxide layer 10. In the illustrated embodiment, the non-uniform thin film 16 can comprise polycrystalline germanium, and the substrate layer 14 can comprise silicon or silicon oxide when the growth is enhanced by the presence of plasma. A heterogeneous material interface is formed between the non-uniform thin film 16 and the substrate layer 14. The non-uniform thin film 16 thus formed using the Volmer-Weber mode results in the formation and growth of isolated clusters or beads gathered around nucleation centers when the energy density in the interface strain (σᵢ) and energy density in the native film (σ_{f}) are, additively, greater than the energy density of the substrate (σₛ). The Volmer-Weber mode can result in a film that has a non-uniform, rough, or beaded surface, or alternatively can result in a polycrystalline film containing voids when formed under suitable circumstances. In accordance with one implementation of the Volmer-Weber mode, surface-wetting agents may not be required for cluster growth.

In modified embodiments, the non-uniform thin film 16 with charge-trapping heterogeneous clusters 20 (FIG. 1) may also include other materials such as polycrystalline silicon germanium compounds grown under the plasma enhanced environment but with additional silicon forming gas. In order to achieve the Volmer-Weber mode, where the energy density in the interface strain (σᵢ) and energy density in the silicon germanium compound film (σ_{f}) are, additively, greater than the energy density of the substrate (σₛ), the gas phase chemical composition needs to be controlled so that the germanium mole fraction of the clusters is greater than 50% through the growth process. The use of heterogeneous compound materials has an advantage in doping effectiveness and a wider range of conductivity in the heterogeneous clusters 20, in addition to morphological differences.

In accordance with an aspect of the present invention, it is preferred that the non-uniform thin film 16 be embodied in a discontinuous material distribution over the substrate 14. In the case of the material forming the thin film 16 being conductive, the resulting film 16 should be non-conductive across the layer 16. In other words, the layer of heterogeneous conductive clusters should be non-conductive across its width and its length. To achieve this discontinuous or nonconductive feature, various implementations of the above disclosure are possible. For example, a Stranski-Krastanov mode of non-uniform thin-film growth, which comprises a hybrid of the Frank-van de Merwe mode and the Volmer-Weber mode, may be implemented in modified embodiments. Thus, in the context of performing heteroepitaxy, the deposition of one material on another, three exemplary growth modes have been discussed, the latter two of which may be more particularly suited or preferred for forming a non-uniform thin film 16 in accordance with the present invention.

Fabrication of a non-uniform trapped-charge memory cell 15 (FIG. 1) may proceed with the provision of an N-type substrate, followed by a P-well implantation into the substrate to thereby form what is referenced herein as a P-type substrate (P-well) in the area of interest. It should be understood that modified embodiments of the present invention may employ a P-type substrate into which an N-well may be implanted. Other embodiments may employ intrinsic semiconductor material such as silicon as a substrate. These and other variations will occur to one skilled in the art of semiconductor fabrication. An isolation structure (not shown), such as a shallow trench isolation (STI), may be formed in the substrate 17 using well-known techniques.

A non-uniform charge-trapping structure 25 (FIG. 1) is then formed on the substrate. In the illustrated embodiment, the non-uniform charge-trapping structure comprises a bottom or tunneling oxide layer 10, a layer of heterogeneous conductive clusters 20 and a top oxide layer 30.

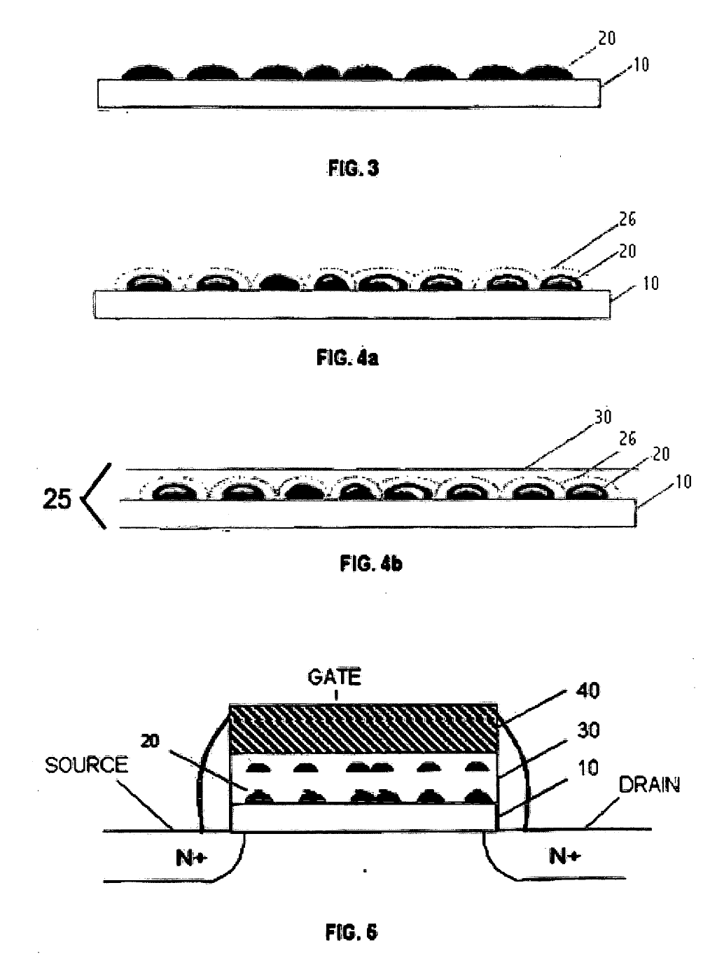

With reference to FIG. 3, the non-uniform charge-trapping structure can be generated by depositing or growing a bottom oxide layer 10 over the substrate to a thickness of, for example, about 50 to 100 angstroms (Å). In accordance with an aspect of the present invention, following formation of the bottom oxide layer 10, a layer of heterogeneous conductive dots or clusters 20 is formed over the bottom oxide layer 10. The heterogeneous conductive clusters 20 may be formed using any of the exemplary techniques disclosed herein. In an illustrative embodiment, the heterogeneous conductive clusters 20 are formed through implementation of a chemical vapor deposition (CVD) growth, with plasma-enhancement, of heterogeneous material and simultaneous in-situ doping. The layer of heterogeneous conductive clusters 20 can be grown in typical embodiments using a low pressure gas-phase process including forming and dopant gases to a thickness ranging from about 25 to about 50 Å, and in an illustrative embodiment can be formed to a thickness of about 30 Å. In typical embodiments, diameters of the heterogeneous conductive clusters 20 can range from about 50 to about 80 Å. In other embodiments, diameters of the heterogeneous conductive clusters 20 can range from about 70 to about 110 Å.

At this stage, some or a percentage of the heterogeneous conductive dots or clusters 20 may contact each other at the edges thereby forming clusters or larger clusters. Referring to FIG. 4, an insulating layer 26 may then be formed over the heterogeneous conductive clusters 20 to seal surfaces and boundaries thereof. The insulating layer 26 can comprise an oxide layer that is thermally grown to a thickness ranging from about 10 to about 20 Å in a typical embodiment.

A top oxide layer 30 is then formed over the insulating layer 26 to obtain the structure shown in FIG. 4b. In a modified embodiment, the insulating layer 26 is omitted and the top oxide layer 30 is formed directly over the heterogeneous conductive clusters 20. Generally, the bottom oxide layer 10 and the top oxide layer 30 (and/or insulating film 25) should be thick enough to prevent the occurrence of electron tunneling between trapped electrons in the layer of heterogeneous conductive clusters 20 and corresponding bit lines, e.g., source region 19 and drain region 21, which may occur at thicknesses below around 50 Å. The top oxide layer 30 thus can be grown or deposited to a thickness of, for example, about 50 to 150 Å. In a typical embodiment, the top oxide layer 30 is formed using a CVD process to a thickness, measured from the upper surface of the bottom oxide 10, ranging from about 30 to about 50 Å.

The typical physical and chemical conditions for the formation of clusters 20 include overall chamber pressure between 100-200 mTorr, helium diluted germane forming gas (1-3% concentration) with a flow rate 10-15 sccm, 200 to 300 sccm argon gas for plasma excitation, helium diluted diborane gas (90-200 ppm concentration) for p-type doping, RF power of 10-20W, and substrate temperature of 350-450C. Additional silane forming gas (1-3% concentration) with a flow rate 10-15 sccm will be needed for the embodiment where a compound is chosen for the formation of heterogeneous trapping layer.

A gate layer 40 can then be deposited using, for example, sputtering or Physical Vapor Deposition (PVD) of polysilicon with doping, on the non-uniform charge-trapping structure 25, followed by patterning and etching of the non-uniform charge-trapping structure 25 and gate layer 40 to form a stacked gate structure. Patterning may comprise forming a bottom anti-reflective coating (BARC) and a layer of photoresist, masking the photoresist, exposing the photoresist to light, and developing the resulting structure to create photoresist bars extending in a bit line direction perpendicularly into the page. The non-stacked gate structure may then be etched with a multi-step etch process that uses the patterned photoresist as a mask. The patterned photoresist and BARC then may be removed using standard strip and ash procedures. Portions of the P-type substrate (P-well) are now exposed, and an ion implantation may be used to increase the concentration of N+ ions, using a dopant such as arsenic or phosphorous, in the exposed the portions of the P-type substrate not covered by the stacked gate structure. The implantation and a following drive-in forms a source region 19 and a drain region 21 in the P-type substrate.

An insulating layer, such as a conforming oxide layer, can then be formed over the resulting structure and anisotropically etched to form insulating sidewalls 33 over sides of the stacked gate structure, thus yielding the structure of FIG. 1. The non-uniform nuclei growth based on a Volmer-Weber mode which in the illustrated embodiment form the heterogeneous conductive clusters 20 can provide confined charge trapping inside the nuclei of the clusters, and scalability of the charge trapping layer and transistors.

The extent of these features can depend on the trapping materials used and morphologies of the clusters, and in some instances it may be desirable to enhance the capacity of the trapping centers. One way to increase the capacity is to grow a second layer of insulated conductive clusters using principles discussed herein, or to grow a plurality of additional layers of insulated conductive clusters. FIG. 5 corresponds to the structure of FIG. 1 with the additional provision of a second non-uniform charge-trapping structure for enhanced storage capacity.

After the structure of FIG. 1 or FIG. 5 is generated, a thermal oxidation process can then be implemented to grow an oxide layer over the source 19 and drain 21 regions in the bit line direction. As presently embodied, the oxide layer is thermally grown between stacked gate structures until a height of the thermally grown oxide is about equal to a height of the stacked gate structures. A layer of polysilicon can then be deposited over the resulting structure, doped, and formed into a plurality of word lines. Regarding this formation, a BARC and photoresist can be applied, patterned, and developed using standard photolithographic techniques, to form a plurality of elongate photoresist structures extending in the word line direction. The elongate photoresist structures are then used to facilitate etching of the layer of polysilicon to form a plurality of elongate control gate or word line structures.

The combination of the bottom oxide layer 10, heterogeneous conductive clusters 20 and top oxide layer 30, together defining the non-uniform charge-trapping structure 25 (FIG. 1), act to trap charge within the heterogeneous conductive clusters 20 and electrically isolate the trapped charge between the bottom oxide layer 10 and the top oxide layer 30. These three layers of the non-uniform charge-trapping structure 25 may be compared to the three layers of a conventional oxide-nitride-oxide (ONO) structure, consisting of a silicon nitride layer disposed between two silicon dioxide layers. The non-uniform trapped-charge memory cell 15 can, in many regards, be fabricated and operated in a manner similar to that of known nitride read-only memory cells, which are known to utilize ONO structures. Thus, the bottom oxide layer 10 and the top oxide layer 30 can correspond to the two silicon oxide layers of an ONO structure, and the heterogeneous conductive clusters 20 can correspond to the nitride layer of the ONO structure.

The nitride layer of a typical ONO structure of a conventional nitride read-only memory is an insulating structure which, in the context of the ONO structure, may be referred to as a charge-trapping layer. A common feature shared between the oxide-encased nitride layer of the ONO structure and the oxide-encased heterogeneous conductive clusters 20 of the present invention is that they both serve as insulated, charge-retaining materials, albeit in different manners. The oxide-encased nitride layer of the prior art comprises a distribution of relatively uniform non-conducting material, whereas the oxide-encased heterogeneous conductive clusters 20 comprises discrete bundles of conductive material. Thus, while charges are stored in the nitride layer, generally in accordance with their entry point and trajectory, charges tend to be stored in the heterogeneous conductive clusters 20 in small groups.

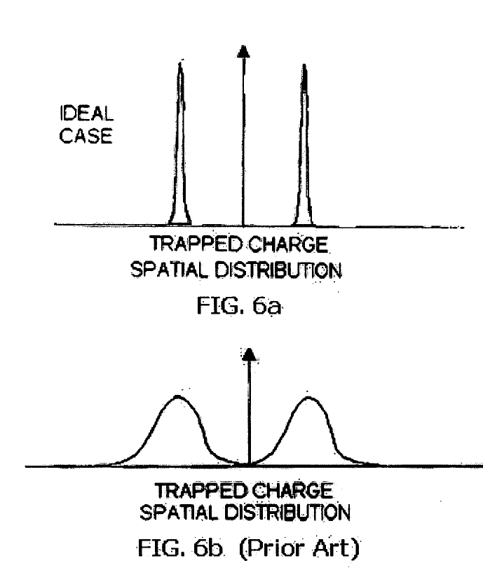

FIG. 6a shows a distribution of trapped-charge in accordance with an ideal case of present invention, wherein the sizes of the individual conductive clusters, which serve as the trapping mechanism for enabling physical 2 bits/cell storage, approach zero. Due to the fact that charges are confined inside the conductive clusters, the spatial distribution of charges can be relatively tight when the clusters are small, which can enable the aggressive scaling of the storage layer as well as the transistor. In comparison, FIG. 6b shows a distribution of trapped-charge in an ONO layer of a typical nitride read-only memory with a uniform nitride (N) layer as the trapping mechanism, which enables physical 2 bits/cell storage wherein charges are not well localized thus limiting process scaling. The distribution of trapped-charge in the heterogeneous conductive clusters 20 of the present invention tend to approximate the distribution of FIG. 6a more so than that of FIG. 6b. Problems which may occur with storing charge in the nitride layer, such as broad distributions of charges causing the two adjacent bits to interfere with each other for device geometries smaller than, for example, about 0.25 μm, may be avoided by the grouping-of-charge characteristic of the heterogeneous conductive clusters 20, so that enhanced scalability and data-retention performance may be achieved. In accordance with the present invention, charge carriers may be tightly confined to the narrow potential wells of the conductive clusters, dots, or quantum.

In the context of a conventional nitride read-only memory cell, having a structure similar to that of FIG. 1 (with the exception of the non-uniform charge-trapping structure 25 being replaced with an ONO structure), various potentials are applied to the source, drain and gate to move charges into and out of up bit and down bit (source and drain) sides of the ONO layer (cf. 25) in order to generate various programmed and erased states. Similarly, for the non-uniform trapped-charge memory cell 15 of FIG. 1, various potentials can applied to the source 19, drain 21 and gate 40 to move charges into and out of up bit 20a and down bit 20b sides of the non-uniform charge-trapping structure 25 in order to generate various programmed and erased states.

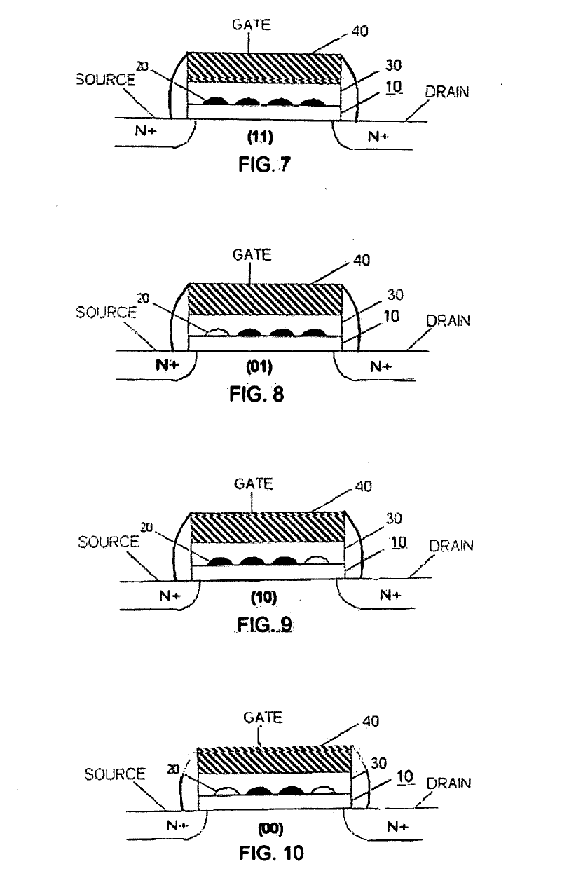

FIGS. 7-10 illustrate the storage of charges in a non-uniform trapped-charge memory cell 15 in accordance with an exemplary embodiment of the programming states (11), (01), (10) and (00). The non-uniform trapped-charge memory cell structure may be operated to store two bits of information per cell to comprise four states which may be labeled (11), (01), (10) and (00). When the heterogeneous conductive clusters 20 are configured by not charging the drain side clusters and not charging the source side clusters, the information stored in the non-uniform trapped-charge memory cell structure may be labeled by the initial state (11). When the conductive clusters are programmed by negatively charging the source-side clusters using well-known techniques and not charging the drain side clusters, the information stored in the non-uniform trapped-charge memory cell structure may be labeled by the state (01). When the conductive clusters are programmed by negatively charging the drain side clusters and not charging the source side clusters, the information stored in the non-uniform trapped-charge memory cell structure may be labeled by the state (10). When the conductive clusters are programmed by negatively charging the drain side clusters and also negatively charging the source side clusters, the information stored in the non-uniform trapped-charge memory cell structure may be labeled by the state (00).

In view of the foregoing, it will be understood by those skilled in the art that the methods of the present invention can facilitate formation and operation of read-only memory devices, and in particular read-only memory devices exhibiting dual bit cell architectures, in an integrated circuit. The above-described embodiments and variations of method have been provided by way of example, and the present invention is not limited to these examples. Multiple variations and modification to the disclosed embodiments will occur, to the extent not mutually exclusive, to those skilled in the art upon consideration of the foregoing description. Additionally, other combinations, omissions, substitutions and modifications will be apparent to the skilled artisan in view of the disclosure herein. Accordingly, the present invention is not intended to be limited by the disclosed embodiments, but is to be defined by reference to the appended claims.

What is claimed is:

1. A memory cell, comprising:
a substrate including a source, a drain and a channel;
at least one charge-trapping structure overlying the channel, the charge-trapping structure comprising a plurality of conductive clusters; and
a gate overlying and insulated from the at least one charge-trapping structure.

2. The memory cell as set forth in claim 1, wherein the plurality of conductive clusters comprises a layer of heterogeneous conductive clusters disposed between two insulator layers.

3. The memory cell as set forth in claim 2, wherein the layer of heterogeneous conductive clusters has a width and a length, and is non-conductive across the width and the length.

4. The memory cell as set forth in claim 2, wherein the conductive clusters are formed of heterogeneous Volmer-Weber growth.

5. The memory cell as set forth in claim 2, wherein the two insulator layers comprise silicon dioxide.

6. The memory cell as set forth in claim 1, wherein the memory cell is an erasable electrically programmable read-only (EEPROM) memory cell.

7. The memory cell as set forth in claim 1, wherein the conductive clusters have widths substantially less than a width of the channel.

8. A method of fabricating a memory cell, comprising:
providing a substrate;
forming at least one charge-trapping structure, which includes a plurality of conductive clusters;
forming a gate layer over, and insulated from, the at least one charge-trapping structure; and
forming a source and a drain.

9. The method of fabricating a memory cell as set forth in claim 8, wherein the forming of at least one charge-trapping structure comprises depositing a tunneling oxide layer, growing a plurality of clusters, oxidizing surfaces of the clusters, and depositing an oxide layer.

10. The method of fabricating a memory cell as set forth in claim 9, wherein the growing of a plurality of clusters comprises chemical vapor deposition (CVD) in the presence of plasma enhancement.

11. The method of fabricating a memory cell as set forth in claim 8, wherein the growing of a plurality of clusters comprises chemical vapor deposition (CVD) in the absence of plasma enhancement.

12. The method of fabricating a memory cell as set forth in claim 8, wherein the growing of a plurality of clusters comprises in-situ doping the plurality of clusters to form conductive clusters.

13. The method of fabricating a memory cell as set forth in claim 8, wherein the forming of a source and a drain comprises:
etching the charge-trapping structure and the gate layer to expose portions of the substrate; and
forming the source and the drain in the exposed portions of the substrate.

14. The method of fabricating a memory cell as set forth in claim 8, wherein the memory cell comprises an electrically erasable read-only memory (EEPROM) cell.

15. The method of fabricating a memory cell as set forth in claim 8, wherein a channel is formed between the source and the drain.

16. A memory cell structure formed using the method of claim 8.

17. A memory cell structure formed using the method of claim 9.

18. A memory cell structure formed using the method of claim 12.
